(19) United States
(12) Patent Application Publication
(10) Pub. No.: US 2024/0321712 A1
(43) Pub. Date: Sep. 26, 2024

(54) CHIP-ON-FILM PACKAGE

(71) Applicant: SAMSUNG ELECTRONICS CO., LTD., Suwon-si (KR)

(72) Inventor: Narae SHIN, Suwon-si (KR)

(21) Appl. No.: 18/607,849

(22) Filed: Mar. 18, 2024

(30) Foreign Application Priority Data
Mar. 24, 2023 (KR) 10-2023-0039110
Jun. 2, 2023 (KR) 10-2023-0071782

(51) Int. Cl. H01L 23/498; H01L 23/00

(52) U.S. Cl. CPC H01L 23/49838; H01L 23/49822; H01L 23/49827; H01L 24/16; H01L 24/32; H01L 24/73; H01L 2224/16225; H01L 2224/32225; H01L 2224/73204

(57) ABSTRACT

A chip-on-film (COF) package including a base film having facing first and second surfaces; a first upper pattern on the first surface and extending in a first direction; second upper patterns on the first surface, the second upper patterns including inner patterns and outer patterns that are spaced apart from each other in the first direction; an upper insulating layer covering the first upper pattern and part of the second upper patterns; lower patterns on the second surface and electrically connecting the inner patterns to the outer patterns; and inner via plugs passing through the base film and electrically connecting the inner patterns of the second upper patterns to the lower patterns, wherein at least one inner pattern is electrically connected to the inner via plug in a region that is not covered by the upper insulating layer.

### CROSS-REFERENCE TO RELATED APPLICATION

This application is based on and claims priority under 35 U.S.C. § 119 to Korean Patent Applications No. 10-2023-0039110, filed on Mar. 24, 2023, and No. 10-2023-0071782, filed on Jun. 2, 2023, in the Korean Intellectual Property Office, the disclosures of which are incorporated by reference herein in their entirety.

### BACKGROUND

### 1. Field

Embodiments relate to a chip-on-film package.

### 2. Description of the Related Art

According to miniaturization and the light-weight trend in electronic appliances, a chip-on-film (COF) package may be provided as high-density semiconductor chip mounting technology. A COF package may include a semiconductor chip bonded to a base film via a flip-chip bonding, and redistribution patterns connected to the semiconductor chip and densely arranged on a substrate.

### SUMMARY

The embodiments may be realized by providing a chip-on-film (COF) package including a base film having a first surface and a second surface, the second surface facing the first surface; at least one first upper pattern on the first surface of the base film and extending in a first direction; a plurality of second upper patterns on the first surface of the base film, the plurality of second upper patterns including inner patterns and outer patterns that are spaced apart from each other in the first direction; an upper insulating layer covering the at least one first upper pattern and part of the second upper patterns; a plurality of lower patterns on the second surface of the base film and electrically connecting the inner patterns to the outer patterns; and inner via plugs passing through the base film and electrically connecting the inner patterns of the second upper patterns to the plurality of lower patterns, wherein at least one of the inner patterns is electrically connected to the inner via plug in a region that is not covered by the upper insulating layer.

The embodiments may be realized by providing a chip-on-film (COF) package including a base film having a first surface and a second surface facing the first surface; a plurality of first conductive patterns including a first upper lead on the first surface of the base film, a first lower lead on the second surface of the base film, and a first via plug electrically connecting the first upper lead to the first lower lead; and a plurality of second conductive patterns including a second upper lead on the first surface of the base film, a second lower lead on the second surface of the base film, and a second via plug electrically connecting the second upper lead to the second lower lead, wherein each first upper lead of the first conductive patterns extends in a first direction, the first upper lead in at least one first conductive pattern of the plurality of first conductive patterns extends straight in the first direction, and the first lower lead and the second lower lead are spaced apart from each other in the first direction.

The embodiments may be realized by providing a chip-on-film (COF) package including a base film having a first surface and a second surface facing the first surface; at least one first upper pattern on the first surface of the base film and extending in a first direction; a plurality of second upper patterns extending on the first surface of the base film in the first direction, and including inner patterns and outer patterns spaced apart from each other in the first direction; and a plurality of lower patterns on the second surface of the base film and electrically connecting the inner patterns to the outer patterns, wherein the second upper patterns include a first group and a second group, and an extending length of the inner patterns of the first group in the first direction is different from an extending length of the inner patterns of the second group.

### BRIEF DESCRIPTION OF THE DRAWINGS

Features will be apparent to those of skill in the art by describing in detail exemplary embodiments with reference to the attached drawings in which:

FIG. 1 is a perspective view schematically showing a chip-on-film (COF) package according to some embodiments;

FIG. 2 is a plan view schematically showing the COF package of FIG. 1;

FIG. 3 is a bottom view schematically showing the COF package of FIG. 1;

FIG. 4 is a cross-sectional view schematically showing the COF package of FIG. 2 taken along line A-A′;

FIG. 5 is a cross-sectional view schematically showing the COF package of FIG. 2 taken along line B-B′;

FIG. 6 is a plan view schematically showing a COF package according to some embodiments;

FIG. 7 is a bottom view schematically showing the COF package of FIG. 6;

FIG. 8 is a plan view schematically showing a COF package according to some embodiments;

FIG. 9 is a perspective view schematically showing a COF package according to some embodiments;

FIG. 10 is a plan view schematically showing the COF package of FIG. 9;

FIG. 11 is a bottom view schematically showing the COF package of FIG. 9;

FIG. 12 is a cross-sectional view schematically showing the COF package of FIG. 9 taken along line C-C′; and

FIG. 13 is a cross-sectional view schematically showing the COF package of FIG. 9 taken along line D-D′.

### DETAILED DESCRIPTION

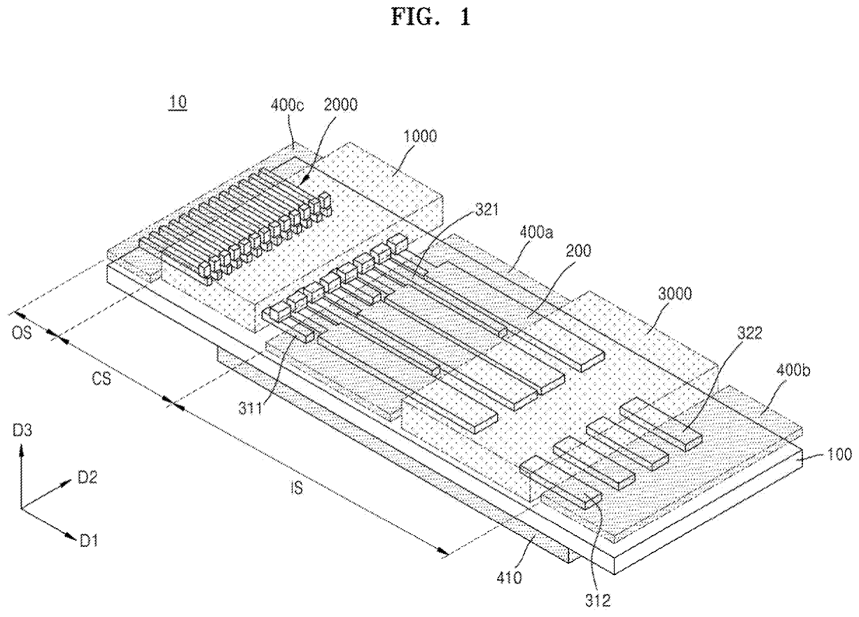

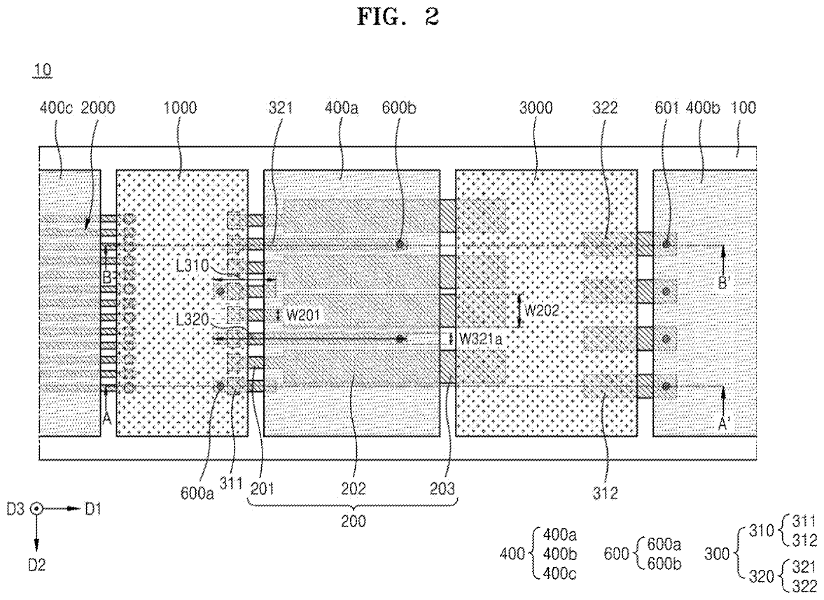

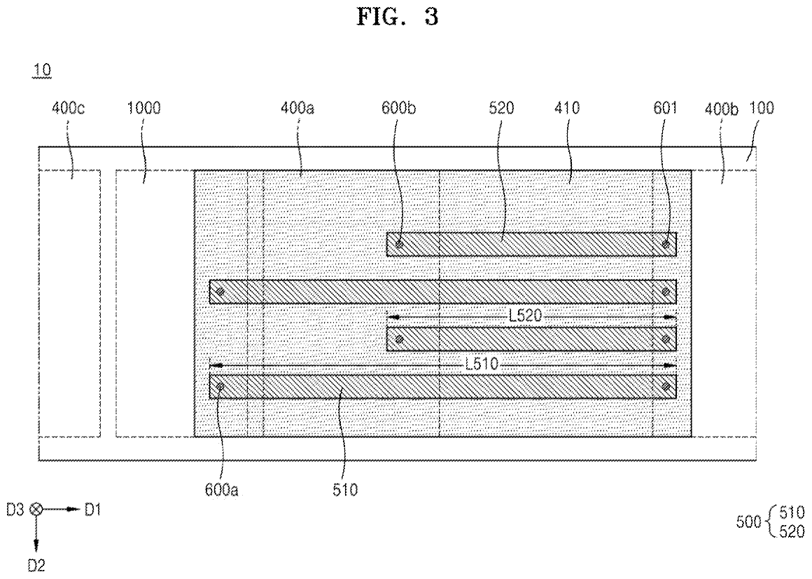

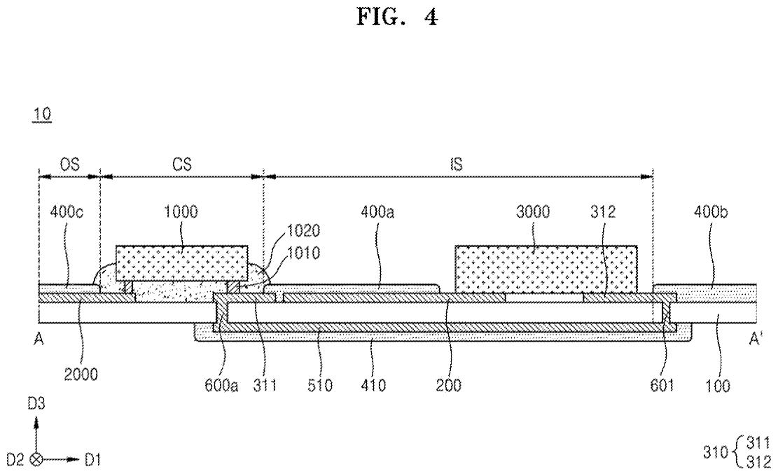

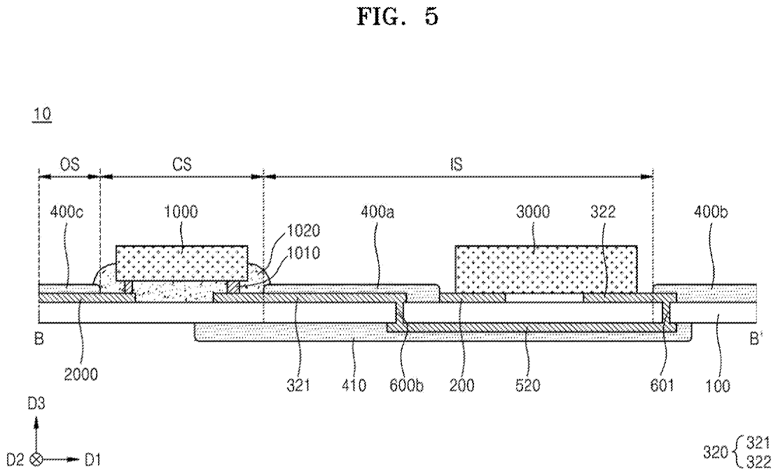

FIG. 1 is a perspective view schematically showing a chip-on-film (COF) package 10 according to one or more embodiments. FIG. 2 is a plan view schematically showing the COF package 10 of FIG. 1. FIG. 3 is a bottom view schematically showing the COF package 10 of FIG. 1. FIG. 4 is a cross-sectional view schematically showing the COF package 10 of FIG. 2 taken along line A-A′. FIG. 5 is a cross-sectional view schematically showing the COF package 10 of FIG. 2 taken along line B-B′.

Referring to FIGS. 1 to 5, the COF package 10 may include a base film 100, a first upper pattern 200, a plurality of second upper patterns 300, an insulating layer 400, a plurality of lower patterns 500, and an inner via plug 600. The COF package 10 may further include an outer via plug 601 and a lower insulating layer 410.

The base film 100 of the COF package 10 may have a semiconductor chip 1000 and a printed circuit board (PCB) 3000 thereon. In an implementation, the base film 100 may include an insulating material. In an implementation, the base film 100 may include a polyimide or an epoxy resin material. In an implementation, the base film 100 may be flexible.

The base film 100 may have a first surface and a second surface. The second surface may face (e.g., may be opposite to) the first surface. In an implementation, the second surface may be spaced apart from the first surface in a perpendicular direction.

In an implementation, the semiconductor chip 1000 and the PCB 3000 may be on the first surface of the base film 100. In an implementation, the semiconductor chip 1000 and the PCB 3000 may be on different surfaces of the base film 100. In an implementation, the semiconductor chip 1000 may be on the first surface of the base film 100 and the PCB 3000 may be on the second surface of the base film 100.

A first direction D1 and a second direction D2 may be parallel to the first surface of the base film 100. The first direction D1 and the second direction D2 may cross perpendicularly to each other. A third direction D3 may be perpendicular to both the first direction D1 and the second direction D2. The third direction D3 may be the (e.g., vertical) direction facing the first and second surfaces of the base film 100.

In an implementation, the base film 100 may include a chip region CS, an input region IS, and an output region OS. The chip region CS may be a region of the base film 100 on which the semiconductor chip 1000 is loaded. The chip region CS may be between the input region IS and the output region OS.

In an implementation, the semiconductor chip 1000 on one surface of the base film 100 may include a display driver integrated circuit (DDI) chip. The semiconductor chip 1000 may operate and control pixels in a display panel.

The semiconductor chip 1000 may include a gate driving integrated circuit for driving gate lines or a data driving integrated circuit for driving data lines. In an implementation, the semiconductor chip 1000 may further include a timing controller, graphic RAM (GRAM), or a power driver, in addition to the DDI. As used herein, the term “or” is not necessarily an exclusive term, e.g., “A or B” would include A, B, or A and B.

The semiconductor chip 1000 may be connected to the first upper pattern 200, the second upper patterns 300, and output patterns 2000 via a plurality of bumps 1010. In an implementation, the insulating layer may not be on the region where the semiconductor chip 1000 is on the first surface of the base film 100, and thus, the first upper pattern 200, the second upper patterns 300, and the output patterns 2000 may be exposed to outside. In an implementation, the plurality of bumps 1010 of the semiconductor chip 1000 may be electrically connected to the first upper pattern 200, the second upper patterns 300, and the output patterns 2000. Contact regions where the plurality of bumps 1010 of the semiconductor chip 1000 and the first upper pattern 200, the second upper patterns 300, and the output patterns 2000 are in contact with each other may be protected by a sealing material 1020.

The input region IS may be at one side of the chip region CS and may be one region of the base film 100 for signal input. In an implementation, the input region IS of the base film 100 may be one region of the base film 100, on which a PCB 3000 is loaded and to which a signal from the PCB 3000 is transferred.

The output region OS may be on the other side of the chip region CS and may be a region of a film substrate 110 for signal output. In an implementation, the output region OS of the base film 100 may be one region of the base film 100, which is connected to the display panel and transfers a signal to the display panel.

The output patterns 2000 in the output region OS may electrically connect the display panel to the semiconductor chip 1000. The output patterns 2000 may extend (e.g., lengthwise) in the first direction D1 and may be spaced apart from one another in the second direction D2. An output region insulating layer 400c may cover the output patterns 2000 to help protect the output patterns 2000 against exposure to the outside and to help prevent shorts among the output patterns 2000. In an implementation, as illustrated in FIG. 1, each of the output patterns 2000 may be on the first surface of the base film 100. In an implementation, the display panel may contact (e.g., directly contact) the first or second surface of the base film 100.

The first upper pattern 200 of the COF package 10 may be on the first surface of the base film 100. The first upper pattern 200 may extend in the first direction D1. One end of the first upper pattern 200 may be connected to the semiconductor chip 1000 and the other end thereof may be connected to the PCB 3000. The first upper pattern 200 may be classified as or may include first to third regions 201, 202, and 203. The second region 202 may be a region covered by an upper insulating layer 400a and may be between the first region 201 and the third region 203.

The first region 201 may be a region where the second upper patterns 300 are at both sides of the first upper pattern 200 and may contact the semiconductor chip 1000. The third region 203 may not be covered by the upper insulating layer 400a and may be exposed to outside, and may contact the PCB 3000.

The first upper pattern 200 may have a plurality of different regions having different horizontal widths (e.g., length in the second direction D2). In an implementation, a horizontal width W202 of the second region 202 may be different from a horizontal width W201 of the first region 201 in the first upper pattern 200. The horizontal width W201 of the first region 201 of the first upper pattern 200 may be less than the horizontal width W202 of the second region 202 and a horizontal width of the third region 203. In an implementation, the first upper pattern 200 may have the increasing horizontal width while extending from the first region 201 to the third region 203 in the first direction D1. In an implementation, the third region 203 of the first upper pattern 200 may be referred to as a contact pad that is electrically connected to the PCB 3000. In an implementation, the third region 203 of the first upper pattern 200 may be referred to as a first row pad.

In an implementation, the horizontal width W202 of the second region 202 in the first upper pattern 200 may be greater than horizontal widths of each of first and second inner patterns 311 and 321 of the second upper patterns 300. In an implementation, the first upper pattern 200 may have increased horizontal width in the region having no second upper patterns 300 at both sides thereof. In an implementation, a signal integrity (SI) performance and power integrity (PI) performance of the first upper pattern 200 may be improved. The first upper pattern 200 and the inner patterns 311 and 321 of the second upper patterns 300 may be spaced apart from each other, and the upper insulating layer 400a may be in the spaced region, so that the first upper pattern 200 and the second upper patterns 300 may not be electrically connected to each other.

In an implementation, the first upper pattern 200 may include a metal material, e.g., copper (Cu), nickel (Ni), aluminum (Al), gold (Au), silver (Ag), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or the like, or an alloy thereof.

The plurality of second upper patterns 300 of the COF package 10 may be on the first surface of the base film 100. The second upper patterns 300 may be spaced apart from each other in the second direction D2.

Each second upper pattern 300 of the plurality of second upper patterns 300 may include the first and second inner patterns 311 and 321 and first and second outer patterns 312 and 322. The first and second inner patterns 311 and 321 and the first and second outer patterns 312 and 322 may be spaced apart from one another in the first direction D1. The region where the first and second inner patterns 311 and 321 and the first and second outer patterns 312 and 322 are separated from each other may be in the input region IS of the base film 100. There may be no conductive material connecting the first and second inner patterns 311 and 321 to the first and second outer patterns 312 and 322 on the first surface of the base film 100, and the first and second inner patterns 311 and 321 and the first and second outer patterns 312 and 322 may not be electrically connected to each other on the first surface.

The first and second inner patterns 311 and 321 of the second upper patterns 300 may be spaced apart from each other in the second direction D2. The first and second inner patterns 311 and 321 may extend in the first direction and may be at least partially covered by the upper insulating layer 400a. One end of the first and second inner patterns 311 and 321 may be connected to the semiconductor chip 1000 and the other end thereof may be covered by the upper insulating layer 400a.

The first and second outer patterns 312 and 322 of each of the second upper patterns 300 may be spaced apart from the first and second inner patterns 311 and 321 in the first direction D1. The first and second outer patterns 312 and 322 may be partially covered by an outer insulating layer 400b. In an implementation, the outer insulating layer 400b and the upper insulating layer 400a may be spaced apart from each other in the first direction D1. The PCB 3000 may be on a space where the outer insulating layer 400b and the upper insulating layer 400a are spaced apart from each other. Other regions of the first and second outer patterns 312 and 322 may be in the space where the outer insulating layer 400b and the upper insulating layer 400a are spaced apart from each other and thus may be exposed to outside. The other regions of the first and second outer patterns 312 and 322 may be referred to as contact pads that are electrically connected to the PCB 3000. The other regions in the first and second outer patterns 312 and 322 may be referred to as second row pads.

In an implementation, the PCB 3000 may include a substrate on which bumps electrically connected to the base film 100 are arranged in two rows spaced apart from each other in the first direction D1. In an implementation, bumps in the first row of the PCB 3000 may be electrically connected to the first row pad and bumps in the second row of the PCB 3000 may be electrically connected to the second row pad. A process of electrically connecting the PCB 3000 to the first row pad and the second row pad may include a bonding process via an anisotropic conductive film (ACF).

The plurality of lower patterns 500 of the COF package 10 may be on the second surface of the base film 100 and may extend in the first direction D1. The lower patterns 500 may be on the lower portions of the first and second inner patterns 311 and 321 and the first and second outer patterns 312 and 322, so as to electrically connect the first and second inner patterns 311 and 321 to the first and second outer patterns 312 and 322. In an implementation, the first and second outer patterns 312 and 322 contacting the PCB may transfer input signals to the first and second inner patterns 311 and 321 via the lower patterns 500, and the first and second inner patterns 311 and 321 receiving the transfer of the input signals may transfer the input signals to the semiconductor chip 1000.

Each of the second upper patterns 300 and each of the lower patterns 500 of the COF package 10 may be electrically connected to each other through the inner and outer via plugs 600 and 601. The inner and outer via plugs 600 and 601 may be in a through-space formed vertically in the base film 100. Upper surfaces of the via plugs 600 and 601 may be electrically connected to the second upper patterns, respectively, and lower surfaces of the inner and outer via plugs 600 and 601 may be electrically connected to the lower patterns 500, respectively.

The inner via plug 600 may electrically connect the first and second inner patterns 311 and 321 of each of the second upper patterns 300 to each of the lower patterns 500, and the outer via plug 601 may electrically connect the first and second outer patterns 312 and 322 in each of the second upper patterns 300 to each of the lower patterns 500.

In an implementation, the second upper patterns 300, the inner via plug 600, the outer via plug 601, and the lower patterns 500 may each include a metal, e.g., copper (Cu), nickel (Ni), aluminum (Al), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or the like, or an alloy thereof.

The second upper patterns 300 may include a first group 310 and a second group 320. The first inner pattern 311 and the first outer pattern 312 may be in the first group 310, and the second inner pattern 321 and the second outer pattern 322 may be in the second group 320. In an implementation, some of the second upper patterns 300 may be the first inner patterns 311, and some other ones of the second upper patterns 300 may be the second inner patterns 321.

The first inner pattern 311 of the second upper pattern 300 in the first group 310 may have a different length in the first direction from that of the second inner pattern 321 of the second upper pattern in the second group 320. In an implementation, a first direction length L310 of the first inner pattern 311 may be different from a first direction length L320 of the second inner pattern 321. In an implementation, the first direction length L310 of the first inner pattern 311 may be less than the first direction length L320 of the second inner pattern 321. That is, the extension length of the first inner pattern 311 in the first direction D1 may be less than the extension length of the second inner pattern 321 in the first direction D1.

In an implementation, one end of each of the first inner pattern 311 and the second inner pattern 321 may not be covered by the upper insulating layer 400a, and another end of each of the first and second inner patterns 311 and 321 may be covered by the upper insulating layer 400a. In an implementation, one end of each of the first inner pattern 311 and the second inner pattern 321 may be spaced apart from the upper insulating layer 400a in the first direction D1. The separation distance between one end of the first inner pattern 311 and the upper insulating layer 400a may be greater than the separation distance between one end of the second inner pattern 321 and the upper insulating layer 400a. In an implementation, an area of the first inner pattern 311, which is not covered by the upper insulating layer 400a, may be greater than that of the second inner pattern 321. In an implementation, one end of the first inner pattern 311 and one end of the second inner pattern 321 may not be at the same plane.

In an implementation, the first outer pattern 312 and the second outer pattern 322 may be spaced apart from each other in the second direction D2. The arrangement order of the first outer pattern 312 and the second outer pattern 322 may correspond to the order of the first inner pattern 311 and the second inner pattern 321.

The inner via plug 600 may include a first inner via plug 600a and a second inner via plug 600b. Some of the first and second inner patterns 311 and 321 of the second upper patterns 300 (e.g., the first inner patterns 311) may be electrically connected to the first inner via plug 600a in the region that is not covered by the upper insulating layer 400a, and remaining ones of first and second inner patterns 311 and 321 of the second upper patterns 300 (e.g., the second inner patterns 321) may be electrically connected to the second inner via plug 600b in the region covered by the upper insulating layer 400a.

In an implementation, the first inner via plug 600a and the second inner via plug 600b may be connected to different second upper patterns 300. A location where the first inner via plug 600a and the second upper pattern 300 are connected to each other may not be in a line (e.g., may be misaligned) with a location where the second inner via plug 600b and the second upper pattern 300 are connected to each other, in the second direction D2.

The second upper patterns 300 connected to the first inner via plug 600a may be in the first group 310. In an implementation, the first inner via plug 600a may be electrically connected to the first inner pattern 311 of the second upper pattern of the first group 310. The second upper patterns 300 connected to the second inner via plug 600b may be in the second group 320. The second inner via plug 600b may be electrically connected to the second inner pattern 321 of the second upper pattern of the second group 320.

The first direction length L310 of the inner pattern to which the first inner via plug 600a is connected may be less than the first direction length L320 of the inner pattern to which the second inner via plug 600b is connected. The first inner via plug 600a may be in the chip region CS, and the second inner via plug 600b may be in the input region IS.

The lower patterns 500 may include a first lower pattern 510 and a second lower pattern 520. A first direction length L510 of the first lower pattern 510 and a first direction length L520 of the second lower pattern 520 may be different from each other. In an implementation, the first direction length L510 of the first lower pattern 510 may be greater than the first direction length L520 of the second lower pattern 520.

In an implementation, the first lower pattern 510 may electrically connect the first inner pattern 311 to the first outer pattern 312 of the first group 310, and the second lower pattern 520 may electrically connect the second inner pattern 321 to the second outer pattern 322 of the second upper pattern of the second group 320. The first lower pattern 510 and the first inner pattern 311 may be electrically connected to each other by the first inner via plug 600a, and the second lower pattern 520 and the second inner pattern 321 may be electrically connected to each other by the second inner via plug 600b.

The first lower pattern 510 and the first inner via plug 600a may be connected to each other at one end of the first lower pattern 510, and the first lower pattern 510 and the outer via plug 601 may be electrically connected to each other at the other end of the first lower pattern 510. The second lower pattern 520 and the second inner via plug 600b are connected to each other at one end of the second lower pattern 520, and the second lower pattern 520 and the outer via plug 601 may be electrically connected to each other at the other end of the second lower pattern 520.

The separation distance between the first inner pattern 311 and the first outer pattern 312 may be greater than the separation distance between the second inner pattern 321 and the second outer pattern 322. In an implementation, a length of the first lower pattern 510 electrically connecting the first inner pattern 311 to the first outer pattern 312 and extending in the first direction D1 may be relatively greater than a length of the second lower pattern 520 electrically connecting the second inner pattern 321 to the second outer pattern 322.

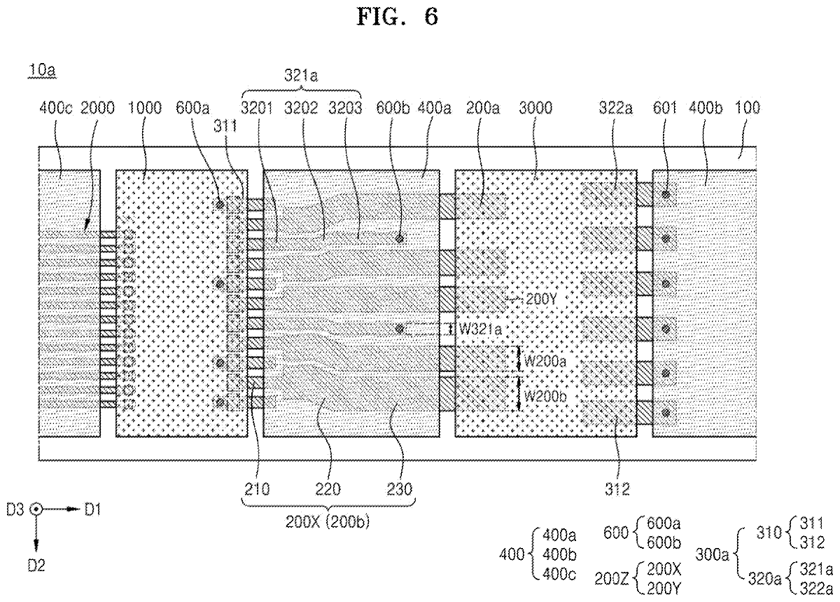

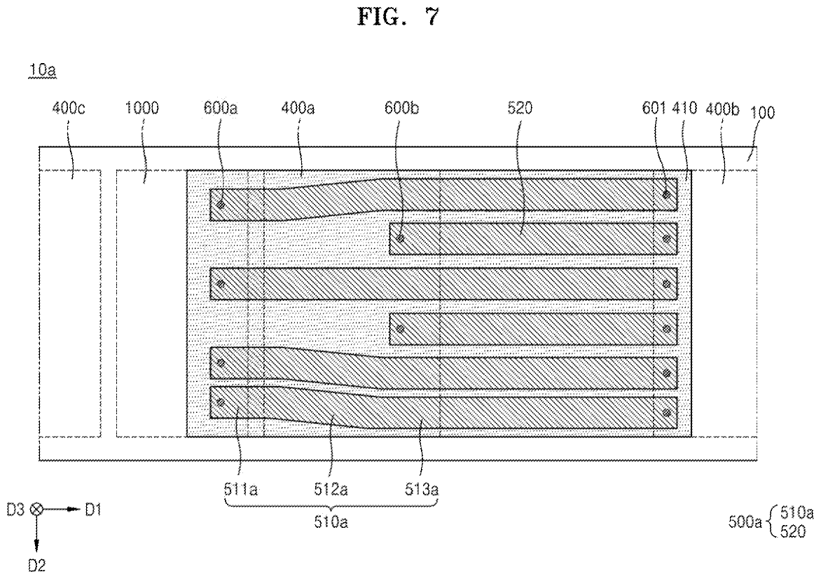

FIG. 6 is a plan view schematically showing a COF package 10a according to one or more embodiments. FIG. 7 is a bottom view schematically showing the COF package 10a of FIG. 6.

Referring to FIGS. 6 and 7, the COF package 10a may include the base film 100, a plurality of first upper patterns 200Z, a plurality of second upper patterns 300a, an insulating layer 400, a plurality of lower patterns 500a, and the inner via plug 600. The COF package 10a may further include an outer via plug 601 and a lower insulating layer 410.

FIGS. 6 and 7 show an embodiment in which the semiconductor chip 1000 and the PCB 3000 (see FIG. 1) are on the first surface of the base film 100. Hereinafter, repeated descriptions of the COF package 10a of FIG. 6 and the COF package 10 (see FIG. 1) may be omitted, and differences are described below.

The plurality of first upper patterns 200Z of the COF package 10a may be on the first surface of the base film 100 and may extend in the first direction D1. The plurality of first upper patterns 200Z and one of the first and second inner patterns 311 and 321a of the plurality of second upper patterns 300a may be alternately arranged. In an implementation, the first upper patterns 200Z and the second upper patterns 300a may be spaced apart from each other in the second direction D2.

The first inner patterns 311 or the second inner patterns 321a of the second upper patterns 300a may be at opposite sides of each of the plurality of first upper patterns 200Z. In an implementation, the extension length of the second inner pattern 321a in the first direction D1 may be greater than that of the first inner pattern 311, and an overlapping length between the second inner pattern 321a and the first upper pattern 200Z may be greater than that between the first inner pattern 311 and the first upper pattern 200Z.

Each of the plurality of first upper patterns 200Z may extend from a bump of the semiconductor chip 1000 to a bump of the PCB 3000. The separation distance between the bumps of the semiconductor chip 1000 in the second direction D2 may be different from the separation distance between the bumps of the PCB 3000 in the second direction D2. Accordingly, the bump of the semiconductor chip 1000 and the bump of the PCB 3000 that are connected by each of the plurality of first upper patterns 200Z may be spaced apart from or offset from each other in the second direction D2. In an implementation, the bump of the semiconductor chip 1000 and the bump of the PCB 3000 that are connected by one first upper pattern may not be in parallel to or aligned along the first direction D1.

The plurality of first upper patterns 200Z may be include bent first upper patterns 200X and straight first upper patterns 200Y.

The bent first upper pattern 200X may include a contact portion 210, a bent portion 220, and an extension portion 230. The contact portion 210 may contact the bumps of the semiconductor chip 1000, the extension portion 230 may contact the bumps of the PCB 3000, and the bent portion 220 may be a bent part connecting the contact portion 210 to the extension portion 230 that are not misaligned along the second direction D2. In an implementation, the contact portion 210 and the extension portion 230 may be partially exposed to outside, and the bent portion 220 may be covered by the upper insulating layer 400a.

The straight first upper pattern 200Y may extend from the bump of the semiconductor chip 1000 to the bump of the PCB 3000 along a straight line (e.g., along an entire length thereof). The straight first upper pattern 200Y may extend parallel to the first direction D1. In an implementation, the straight first upper pattern 200Y may contact a central bump of the bumps of the semiconductor chip 1000.

In an implementation, the plurality of first upper patterns 200Z may include a first group 200a and a second group 200b.

The first group 200a may include the first upper patterns 200Z that have the first inner pattern 311 at one side and the second inner pattern 321a at the other side, and the second group 200b may include the first upper patterns 200Z that have the first inner patterns 311 at opposite sides thereof.

A horizontal width W200a of the first upper pattern in the first group 200a may be different from a horizontal width W200b of the first upper pattern in the second group 200b (e.g., as measured in the second direction D2). In an implementation, the horizontal width W200a of the first upper pattern in the first group 200a may be less than the horizontal width W200b of the first upper pattern in the second group 200b. In order to maintain the distance from the second inner pattern 321a, the horizontal width W200a of the first upper pattern in the first group 200a may be less than the horizontal width W200b of the first upper pattern in the second group 200b. In an implementation, the horizontal width W200a of the first upper pattern of the first group 200a and the horizontal width W200b of the first upper pattern of the second group 200b may be greater than a horizontal width W321a of the second inner pattern 321a. In an implementation, the horizontal widths may be reduced in an order of the first upper pattern of the second group 200b, the first upper pattern of the first group 200a, and the second inner pattern 321a.

In an implementation, the horizontal width W200a of the first upper pattern of the first group 200a may be about 30 μm to about 70 μm. The horizontal width W321a of the second inner pattern 321a may be about 10 μm to about 30 μm. The horizontal width W200a of the first upper pattern of the first group 200a and the horizontal width W200b of the first upper pattern of the second group 200b may be greater than the horizontal width W321a of the second inner pattern 321a, and the electrical characteristics of the COF package 10a may be improved. In an implementation, the first upper patterns 200Z may have improved SI and PI performances.

Some of the first and second inner patterns 311 and 321a of the second upper patterns 300a may be the first inner patterns 311 and the others may be the second inner patterns 321a. The first inner pattern 311 may have opposite ends extending parallel to or straight along the first direction D1, and the second inner pattern 321a may be curved or bent.

In an implementation, the second inner pattern 321a may include a contact portion 3201, a bent portion 3202, and an extension portion 3203. The contact portion 3201 may be a region contacting the bump of the semiconductor chip 1000, the extension portion 3203 may be a region contacting the second inner via plug 600b, and the bent portion 3202 may be a region that is curved or bent and connects the contact portion 3201 to the extension portion 3203 (that are spaced apart from or offset from each other in the second direction D2).

The plurality of lower patterns 500a may include a first group 510a and the second lower patterns 520. The first group 510a may include lower patterns that are electrically connected to the straight second upper patterns 300a, and the second lower patterns 520 may include lower patterns that are electrically connected to the bent second upper patterns 300a.

The second lower pattern 520 may extend linearly in the first direction D1. In an implementation, the second inner via plug 600b electrically connecting the second lower pattern 520 to the second inner pattern 321a and the bump of the PCB 3000 may be aligned on one straight line in the first direction D1, and the second lower pattern 520 may extend in a direction parallel to the first direction D1.

In an implementation, at least some lower patterns of the first group 510a may include a contact portion 511a, a bent portion 512a, and an extension portion 513a. The contact portion 511a may be a region contacting the first inner via plug 600a, the extension portion 513a may be a region contacting the bump of the PCB 3000, and the bent portion 512a may be a bent potion that connects the contact portion 511a to the extension portion 513a that are spaced apart from or offset relative to each other in the second direction D2. In an implementation, the first inner via plug 600a and the bump of the PCB 3000 may not be aligned on the straight line in the first direction D1, and at least some lower patterns of the first group 510a may have curved shapes.

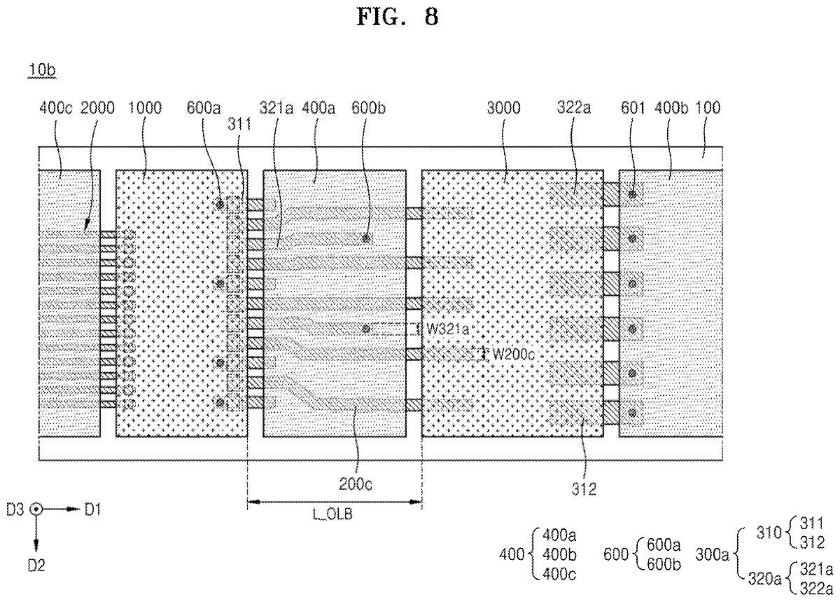

FIG. 8 is a plan view schematically showing a COF package 10b according to one or more embodiments.

Hereinafter, repeated descriptions of the COF package 10b of FIG. 8 and the COF package 10a (see FIG. 6) may be omitted, and differences are described below.

At least some first upper patterns 200c of the COF package 10b may be bent in the second direction D2 based on the first direction D1. In an implementation, at least some of the first upper patterns 200c may include the bent portions described above. In an implementation, the first upper patterns 200c may connect the bumps of the semiconductor chip 1000 to the bumps of the PCB 3000 that are spaced apart or offset from each other in the second direction D2.

A horizontal width W200c (e.g., in the second direction D2) of each of the first upper patterns 200c may be substantially the same as a horizontal width W321a of the inner patterns 311 and 321a of each of the second upper patterns 300a. The first group 310 including the first inner patterns 311 may extend linearly on the first surface of the base film 100, and thus, the number of patterns having the bent portions on the first surface of the base film 100 may be reduced. Due to the reduction in the number of the bent portions, the extending lengths of the first upper patterns 200c in the first direction D1 may be reduced. In an implementation, a first direction length L_OLB between the semiconductor chip 1000 and the PCB 3000 may be reduced, and the size of the COF 10b may be reduced.

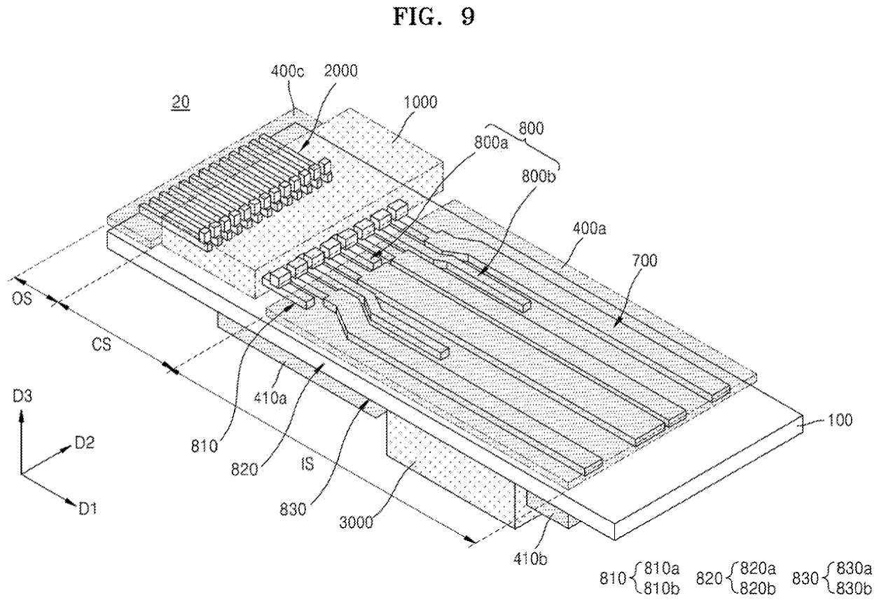

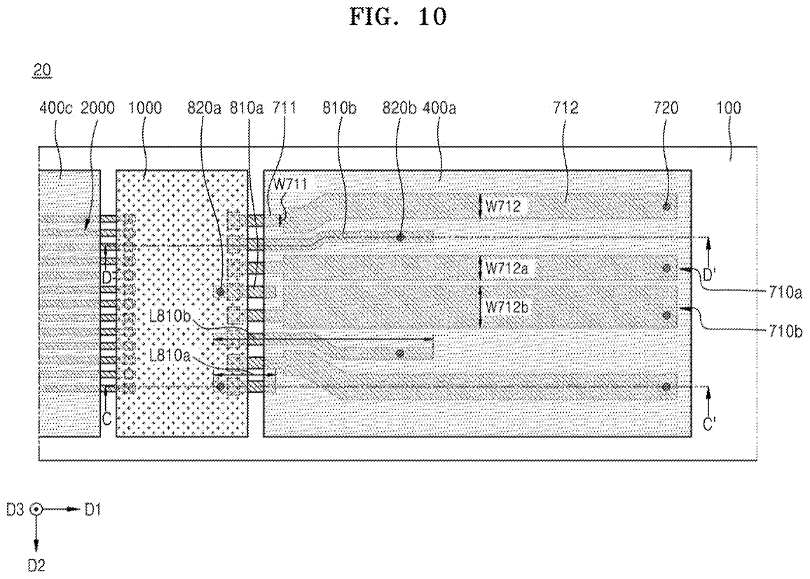

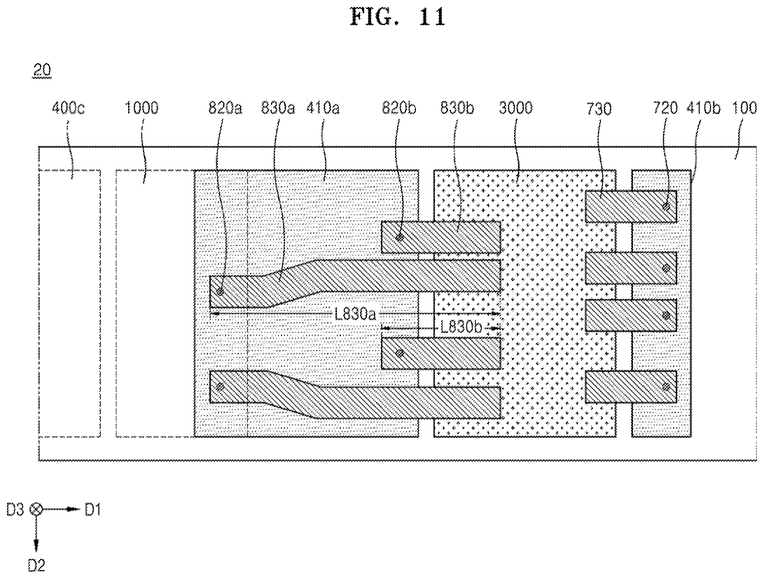

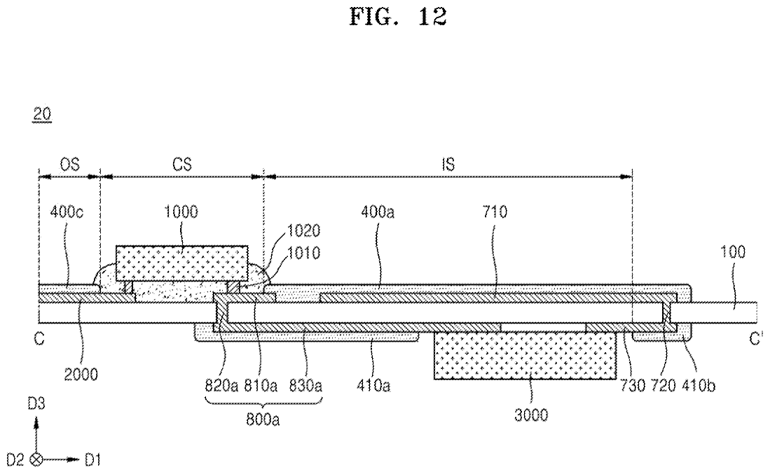

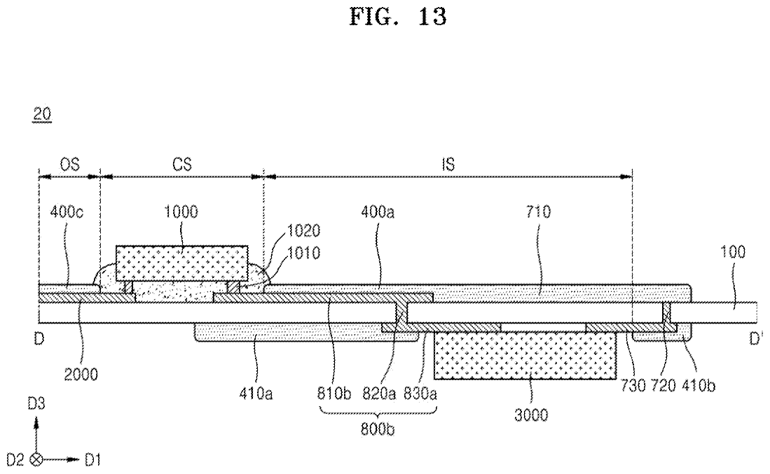

FIG. 9 is a perspective view schematically showing a COF package 20 according to one or more embodiments. FIG. 10 is a plan view schematically showing the COF package 20 of FIG. 9. FIG. 11 is a bottom view schematically showing the COF package 20 of FIG. 9. FIG. 12 is a cross-sectional view schematically showing the COF package 20 of FIG. 9 taken along line C-C′. FIG. 13 is a cross-sectional view schematically showing the COF package 20 of FIG. 9 taken along line D-D′.

Referring to FIGS. 9 to 13, the COF package 20 may include the base film 100, a plurality of first conductive patterns 800, a plurality of second conductive patterns 700, an insulating layer 400, a lower insulating layer 410a, and an outer insulating layer 410b. The base film 100 of the COF package 20 may have the semiconductor chip 1000 and the PCB 3000 thereon. In an implementation, referring to FIGS. 9 to 13, the semiconductor chip 1000 and the PCB 3000 may be on different surfaces of the base film 100.

An output region insulating layer 400c and the upper insulating layer 400a on the first surface of the base film 100 may be spaced apart from each other in the second direction D2. The semiconductor chip 1000 may be in a space where the output region insulating layer 400c and the upper insulating layer 400a are spaced apart from each other. In an implementation, the semiconductor chip 1000 may be on the first surface of the base film 100.

The outer insulating layer 410b and the lower insulating layer 410a on the second surface of the base film 100 may be spaced apart from each other in the second direction D2. The PCB 3000 may be in a space where the outer insulating layer 410b and the lower insulating layer 410a are spaced apart from each other. In an implementation, the PCB 3000 may be on the second surface of the base film 100.

Hereinafter, repeated descriptions of the COF package 20 of FIG. 9 and the COF package 10 of FIG. 1 may be omitted, and differences are described below. The base film 100, the semiconductor chip 1000, the output patterns 2000, and the PCB 3000 of FIG. 9 may be substantially the same as the base film 100, the semiconductor chip 1000, the output patterns 2000, and the PCB 3000 (see FIG. 1).

Each of the plurality of first conductive patterns 800 in the COF package 20 may include a first upper lead 810, a first lower lead 830, and a first via plug 820. The first upper lead 810 may be on the first surface of the base film 100 and may extend in the first direction D1. The first lower lead 830 may be on the second surface of the base film 100 and may extend in the first direction D1. The first via plug 820 may electrically connect the first upper lead 810 to the first lower lead 830. The first via plug 820 may pass through the base film 100. In an implementation, the first via plug 820 may pass through the base film 100 so that an upper surface thereof contacts the first upper lead 810 and a lower surface thereof contacts the first lower lead 830.

Each of the plurality of second conductive patterns 700 of the COF package 20 may include a second upper lead 710, a second lower lead 730, and a second via plug 720. The second upper lead 710 may be on the first surface of the base film 100 and may extend in the first direction D1. The second lower lead 730 may be on the second surface of the base film 100 and may extend in the first direction D1. The second via plug 720 may electrically connect the second upper lead 710 to the second lower lead 730. The second via plug 720 may pass through the base film 100. In an implementation, the second via plug 720 may pass through the base film 100 so that an upper surface thereof contacts the second upper lead 710 and a lower surface thereof contacts the second lower lead 730.

In an implementation, the first conductive patterns 800 and the second conductive patterns 700 may each include a metal material, e.g., copper (Cu), nickel (Ni), aluminum (Al), gold (Au), silver (Ag), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or the like, or an alloy thereof.

The first upper lead 810 and the second upper lead 710 may be covered by the upper insulating layer 400a. In an implementation, in the first upper lead 810 and the second upper lead 710, parts that are electrically connected to the semiconductor chip 1000 may not be covered by the upper insulating layer 400a. In an implementation, one end of the first upper lead 810 and the second upper lead 710 may be exposed to outside, and the other end thereof may be covered by the upper insulating layer 400a.

The first via plug 820 and the second via plug 720 may be spaced apart from each other in the first direction D1. In an implementation, the first via plug 820 may be closer to the semiconductor chip 1000 than the second via plug 720 is to the semiconductor chip 1000. The first upper lead 810 may extend from the bump of the semiconductor chip 1000 to the first via plug 820, and the second upper lead 710 may extend from the bump of the semiconductor chip 1000 to the second via plug 720. In an implementation, the first via plug 820 may be closer to the semiconductor chip 1000 than the second via plug 720 is to the semiconductor chip 1000, and a length of the first upper lead 810 in the first direction may be less than that of the second upper lead 710 in the first direction.

The first upper lead 810 may have a length extending in the first direction D1, which may be less than that of the second upper lead 710, and thus, the second upper lead 710 may include a region where the first upper lead 810 is on at least one side thereof and a region where the first upper lead 810 is not at a side thereof. A first region 711 of the second upper lead 710 may be a region where the first upper lead 810 is on at least one of opposite sides thereof, and a second region 712 is a region where the first upper lead 810 is not located on opposite sides thereof. In an implementation, a horizontal width (length in the second direction D2) of the second upper lead 710 may be greater in the second region 712 than in the first region 711. In an implementation, the second region 711 of the second upper lead 710 may not have the first upper leads 810 at opposite sides thereof and thus may have relatively large horizontal width W712. In an implementation, the first region 711 of the second upper lead 710 may have the first upper lead 810 at one side thereof and thus may have a relatively small horizontal width W711 in order to maintain an interval from the first upper lead 810.

In an implementation, the second upper lead 710 may be a bent line extending in the first direction D1. In an implementation, the second upper lead 710 may include a contact portion, a bent portion, and an extension portion. The contact portion of the second upper lead 710 may be a straight portion contacting the bump of the semiconductor chip 1000, the extension portion may be a straight portion connected to the second via plug 720, and the bent portion may connect the contact portion to the extension portion that are spaced apart from each other in the second direction D2. In an implementation, the bump of the semiconductor chip 1000 may be spaced apart from the second via plug 720 in the second direction D2, and the second upper lead 710 may have a curved or bent shape.

Some of the plurality of first conductive patterns 800 may include the first upper lead 810 extending linearly. Hereinafter, the first upper lead 810 extending linearly is referred to as a straight first upper lead 810a. The straight first upper lead 810a may extend from one end to the other end thereof. In an implementation, the straight first upper lead 810a may extend in the direction parallel to the first direction D1. The straight first upper lead 810a may have a length that is substantially the same as that of the contact portion of the second upper lead 710.

Remaining first conductive patterns from among the plurality of first conductive patterns 800 may each include the first upper lead 810 extending in or along a bent line. Hereinafter, the first upper lead 810 extending while being bent is referred to as a bent first upper lead 810b. The bent first upper lead 810b may include a region that is bent while extending from one end to the other end thereof.

In the bent region of the bent first upper lead 810b, the bent direction may be parallel to or the same as the bent direction of the second upper lead 710 at the bent portion. In an implementation, the extending length of the bent first upper lead 810b may be substantially the same as the extending length of the second upper lead 710 from the contact portion to the bent portion. In an implementation, an extending length L810b of the bent first upper lead 810b may be greater than an extending length L810a of the straight first upper lead 810a.

The first via plug 820 connected to the straight first upper lead 810a may be a straight via plug 820a, and the first via plug 820 connected to the bent first upper lead 810b may be a bent via plug 820b. The straight via plug 820a may be closer to the bump of the semiconductor chip 1000 than the bent via plug 820b is to the bump of the semiconductor chip 1000.

In an implementation, the straight first upper lead 810a and the straight via plug 820a may be connected to each other in a region where the straight first upper lead 810a is not covered by the upper insulating layer 400a. The straight first upper lead 810b and the bent via plug 820b may be connected to each other in a region where the bent first upper lead 810b is covered by the upper insulating layer 400a.

In an implementation, the straight via plug 820a may be under the semiconductor chip 1000 in the vertical direction. In an implementation, the straight via plug 820a may contact the straight first upper lead 810a in the region in the straight first upper lead 810a, the region being located perpendicularly under the semiconductor chip 1000. In an implementation, the straight via plug 820a may be closer to the output patterns 2000 than the bump of the semiconductor chip 1000.

In an implementation, in the contact portion of the second upper lead 710, the straight first upper lead 810a or the bent first upper lead 810b may be at opposite sides of the second upper lead 710, and in the bent portion of the second upper lead 710, the bent first upper lead 810b may be at one side of the second upper lead 710. In the extension portion of the second upper lead 710, the first upper lead 810 may not be at opposite sides of the second upper lead 710. Accordingly, the horizontal width of the second upper lead 710 may be less in the contact portion than in the bent portion and the extension portion.

In an implementation, the horizontal widths of the second upper leads 710 in the plurality of second conductive patterns 700 may be different from one another. In an implementation, the horizontal width W712 of the second upper lead 710 may vary depending on whether there is the first upper lead 810 at opposite sides of the second upper lead 710 and the kinds of the first upper lead 810. In an implementation, the horizontal width W712 of the second upper lead 710 may vary depending on the signals transferred by the second conductive patterns 700. In an implementation, from among the second conductive patterns 700, the horizontal width W712b of the second upper lead 712b in the second conductive pattern configured to transfer a power signal may be greater than a horizontal width W712a of the second upper lead 712a in the second conductive pattern configured to transfer another signal.

The first lower lead 830 and the second lower lead 730 may be spaced apart from each other in the first direction D1. The first lower lead 830 and the second lower lead 730 may be spaced apart and may not be electrically connected to each other. The first lower lead 830 and the second lower lead 730 may be each electrically connected to the bumps of the PCB 3000.

In an implementation, the bumps of the PCB 3000 may be arranged in two rows. The bumps in the first row may be connected to the first lower lead 830 and the bumps in the second row may be connected to the second lower lead 730. The first lower lead 830 may receive signals transferred from the bumps in the first row and may transfer the signals to the semiconductor chip 1000 via the first via plug 820 and the first upper lead 810. The second lower lead 730 may receive signals transferred from the bumps in the second row and may transfer the signals to the semiconductor chip 1000 via the second via plug 720 and the second upper lead 710.

The first lower lead 830 may be the straight first lower lead 830b or the bent first lower lead 830a. The straight first lower lead 830b may extend linearly in parallel to the first direction D1 from the bumps of the PCB 3000 to the first via plug 820. The bent first lower lead 830a may extend to include the bent portion from the bumps of the PCB 3000 to the first via plug 820.

In an implementation, the bent first lower lead 830a may include a contact portion, a bent portion, and an extension portion. The contact portion may be connected to the first via plug 820, the extension portion may be connected to the bumps of the PCB, and the bent portion may be a curved or bent portion connecting the contact portion to the extension portion that are spaced apart from each other in the second direction D2. In an implementation, the bumps of the PCB 3000 and the first via plug 820 may be spaced apart from each other in the second direction D2, and the bent first lower lead 830a may have the curved shape.

In an implementation, the interval between the bumps of the semiconductor chip 1000 in the second direction D2 and the interval between the bumps of the PCB 3000 in the second direction D2 may be different from each other, and the first conductive patterns 800 may have the bent portion in at least a part thereof. In an implementation, the first conductive patterns 800 may each have a lead of a bent shape on the first surface or the second surface of the base film 100.

In an implementation, the plurality of first conductive patterns 800 may include a first group 800a and a second group 800b. The first group 800a may include the first conductive patterns 800 on which the leads bent on the second surface of the base film 100 are arranged, and the second group 800b may include the first conductive patterns 800 on which the leads bent on the first surface of the base film 100 are arranged.

The first group 800a may include the first conductive pattern 800 including the straight first upper lead 810a, the straight via plug 820a, and the bent first lower lead 830a, and the second group 800b may include the first conductive pattern 800 including the bent first upper lead 810b, the bent via plug 820b, and the straight second lower lead 830b. In an implementation, the straight via plug 820a may electrically connect the straight first upper lead 810a to the bent first lower lead 830a, and the bent via plug 820b may electrically connect the bent first upper lead 810b to the straight first lower lead 830b.

In an implementation, an extension length L830b (e.g., in the first direction D1) of the straight first lower lead 830b may be less than an extension length L830a of the bent first lower lead 830a. The straight first lower lead 830b may extend from the bumps from the PCB 3000 to the bent via plug 820b, and the bent first lower lead 830a may extend from the bumps of the PCB 3000 to the straight via plug 820a. The straight via plug 820a may be farther from the PCB 3000 than the bent via plug 820b is to the PCB 3000, and thus, the bent first lower lead 830a may be longer than the straight first lower lead 830b.

The extending length of the straight first upper lead 810a of the first group 800a may be relatively small. In an implementation, the number of leads arranged on the first surface of the base film 100 and having the bent portions may be reduced.

In an implementation, the horizontal width of the second upper lead 710 of each of the second conductive patterns 700 may increase. In an implementation, the horizontal width of the second upper lead 710 and the resistance of the second upper lead 710 may be reduced, and the SI and PI performance of the second conductive patterns 700 may be improved.

In an implementation, the horizontal width of the second upper lead 710 may be constantly maintained, and the first direction length of the second upper lead 710 may be reduced. In an implementation, the length of the COF package 20 in the first direction may be reduced.

By way of summation and review, the number of bumps in a printed circuit board for inputting signals to a high-performance semiconductor chip has been increasing.

One or more embodiments may provide a chip-on-film (COF) package having opposite surfaces on which redistribution patterns connected to a printed circuit board are arranged.

One or more embodiments may provide a COF package in which a width of each redistribution pattern is increased or a length of each redistribution pattern is reduced.

One or more embodiments may provide a chip-on-film package including a via plug.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A chip-on-film (COF) package, comprising:
a base film having a first surface and a second surface, the second surface facing the first surface;
at least one first upper pattern on the first surface of the base film and extending in a first direction;
a plurality of second upper patterns on the first surface of the base film, the plurality of second upper patterns including inner patterns and outer patterns that are spaced apart from each other in the first direction;
an upper insulating layer covering the at least one first upper pattern and part of the second upper patterns;
a plurality of lower patterns on the second surface of the base film and electrically connecting the inner patterns to the outer patterns; and
inner via plugs passing through the base film and electrically connecting the inner patterns of the second upper patterns to the plurality of lower patterns,
wherein at least one of the inner patterns is electrically connected to the inner via plug in a region that is not covered by the upper insulating layer.

2. The COF package as claimed in claim 1, wherein:
the inner patterns include first inner patterns and second inner patterns, and
a length of each first inner pattern in the first direction is different from a length of each second inner pattern in the first direction.

3. The COF package as claimed in claim 2, wherein:
the length of each first inner pattern in the first direction is less than the length of each second inner pattern in the first direction, and
each first inner pattern contacts the inner via plug in the region that is not covered by the upper insulating layer.

4. The COF package as claimed in claim 3, wherein:
the at least one first upper pattern includes a first region and a second region,
the first region is a region in which the first inner patterns are at opposite sides of the at least one first upper pattern,
the second region is a region in which the first inner patterns are not at at least one of the opposite sides of the at least one first upper pattern, and
a length of the second region in a second direction that is perpendicular to the first direction is smaller than a length of the first region in the second direction.

5. The COF package as claimed in claim 3, wherein:
the plurality of lower patterns include a first lower pattern and a second lower pattern,
the first lower pattern is electrically connected to the first inner pattern,
the second lower pattern is electrically connected to the second inner pattern, and
a length of the first lower pattern in the first direction is greater than a length of the second lower pattern in the first direction.

6. The COF package as claimed in claim 5, wherein the first lower pattern has a bent shape.

7. The COF package as claimed in claim 1, wherein the at least one first upper pattern and the inner patterns of the second upper patterns are spaced apart from each other in a second direction that is perpendicular to the first direction.

8. The COF package as claimed in claim 7, wherein a length of the at least one first upper pattern in the first direction is greater than a length of each inner pattern of the second upper patterns in the first direction.

9. The COF package as claimed in claim 7, wherein the at least one first upper pattern includes a plurality of regions having different lengths in the second direction.

10. The COF package as claimed in claim 1, wherein:
the at least one first upper pattern includes a plurality of first upper patterns, and
the plurality of first upper patterns have different lengths in a second direction perpendicular to the first direction.

11. A chip-on-film (COF) package, comprising:
a base film having a first surface and a second surface facing the first surface;
a plurality of first conductive patterns including:
a first upper lead on the first surface of the base film,
a first lower lead on the second surface of the base film, and
a first via plug electrically connecting the first upper lead to the first lower lead; and
a plurality of second conductive patterns including:
a second upper lead on the first surface of the base film,
a second lower lead on the second surface of the base film, and
a second via plug electrically connecting the second upper lead to the second lower lead,
wherein:
each first upper lead of the first conductive patterns extends in a first direction,
the first upper lead in at least one first conductive pattern of the plurality of first conductive patterns extends straight in the first direction, and
the first lower lead and the second lower lead are spaced apart from each other in the first direction.

12. The COF package as claimed in claim 11, wherein, from among the plurality of first conductive patterns, the first lower lead in the plurality of first conductive patterns, of which the first upper lead straightly extends in the first direction, is bent.

13. The COF package as claimed in claim 11, further comprising an upper insulating layer covering at least part of the first upper lead of the plurality of first conductive patterns and at least part of the second upper lead of the plurality of second conductive patterns.

14. The COF package as claimed in claim 13, wherein, from among the plurality of first conductive patterns, the first via plug in the plurality of first conductive patterns, of which the first upper lead straightly extends in the first direction, is in a region that is not covered by the upper insulating layer.

15. The COF package as claimed in claim 11, wherein the first upper lead of some of the plurality of first conductive patterns has a bent shape.

16. The COF package as claimed in claim 11, wherein:
the plurality of first conductive patterns include a first group and a second group,
the first group includes the first conductive patterns in which the first upper lead extends straight in the first direction,
the second group includes the first conductive patterns in which the first upper lead extends in the first direction while being bent, and
an extending length of the first upper lead in the first group is less than an extending length of the first upper lead in the second group.

17. The COF package as claimed in claim 11, further comprising a semiconductor chip electrically connected to the first upper lead of the plurality of first conductive patterns and the second upper lead of the plurality of second conductive patterns,
wherein, from among the plurality of first conductive patterns, the first via plug of the plurality of first conductive patterns, of which the first upper lead straightly extends in the first direction, is perpendicularly under the semiconductor chip.

18. A chip-on-film (COF) package, comprising:
a base film having a first surface and a second surface facing the first surface;
at least one first upper pattern on the first surface of the base film and extending in a first direction;
a plurality of second upper patterns extending on the first surface of the base film in the first direction, and including inner patterns and outer patterns spaced apart from each other in the first direction; and
a plurality of lower patterns on the second surface of the base film and electrically connecting the inner patterns to the outer patterns,
wherein:
the second upper patterns include a first group and a second group, and
an extending length of the inner patterns of the first group in the first direction is different from an extending length of the inner patterns of the second group.

19. The COF package as claimed in claim 18, wherein an extending length in the first direction of the inner patterns of the first group is less than an extending length in the first direction of the inner patterns of the second group.

20. The COF package as claimed in claim 19, further comprising:
an inner via plug passing through the base film and electrically connecting the inner patterns of the second upper patterns to the plurality of lower patterns; and
an outer via plug passing through the base film and electrically connecting the outer patterns of the second upper patterns to the plurality of lower patterns,
wherein the inner via plug connected to the second upper pattern of the first group is closer to the outer via plug than the inner via plug connected to the second upper pattern of the second group is to the outer via plug.
